(19) United States
(12) Patent Application Publication
(10) Pub. No.: US 2026/0243822 A1
(43) Pub. Date: Aug. 20, 2026

(54) SELECT GATE SCAN USING DOUBLE VERIFY

(71) Applicant: Micron Technology, Inc., Boise, ID (US)

(72) Inventors: Lei Lin, Fremont, CA (US); Luis Iam, San Jose, CA (US); Jianmin Huang, San Carlos, CA (US)

(21) Appl. No.: 19/056,473

(22) Filed: Feb. 18, 2025

(51) Int. Cl. G01R 31/3185

(52) U.S. Cl. CPC G01R 31/318544; G01R 31/318577

(57) ABSTRACT

A system and method are provided for retiring blocks in a memory device. The system and method perform a first select gate (SG) scan operation on a memory portion of a memory device. After performing the first SG scan operation, the system and method selectively perform a second SG scan operation on the memory portion, the second SG scan operation having different verification operations than the first SG scan operation. The system and method selectively perform one or more SG maintenance operations on the memory portion based on a result of performing at least one of the first SG scan operation and the second SG scan operation on the memory portion.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates a diagram of different results of performing select gate (SG) scan operations, in accordance with some examples.

FIG. 3 illustrates a diagram of waveforms for performing SG scan operations, in accordance with some examples.

FIG. 4 illustrates a table for performing SG maintenance operations, in accordance with some examples.

FIG. 5 illustrates a flow diagram of operations performed using the media operations manager, in accordance with some examples.

FIG. 6 illustrates a flow diagram of operations performed using the media operations manager, in accordance with some examples.

FIG. 7 is a block diagram of an example computer system, in accordance with some examples.

### DETAILED DESCRIPTION

The present disclosure configures a memory device and processing device to perform double-verify SG scan operations to intelligently determine when to perform SG maintenance operations. Specifically, when monitoring a portion of the memory device (e.g., a virtual block (VB) or memory block), the processing device performs a first SG scan operation to determine if voltage thresholds are within a safe range. For memory portions that fail the first SG scan, the processing device performs a second SG scan operation with different verification criteria to obtain a more accurate distribution of SG voltage threshold (VT) levels. The processing device can selectively perform SG maintenance operations, including touch-up (TU) programming and/or special erase operations, based on the results of the two SG scan operations. When both scans fail, both TU and special erase operations may be performed. When the first scan passes but the second fails, only TU may be performed without special erase. When both scans pass, neither operation is needed. This approach prevents leakage issues while optimizing system performance by avoiding unnecessary special erase operations. The double-verify SG scan provides more precise information about the SG VT distribution, allowing the system to determine if the VT levels are still high enough to prevent leakage even when failing a low SG VT scan. Additionally, the system can perform the SG scans in reverse order, starting with the higher verify voltage, which provides faster scan performance and allows skipping the second scan if the first scan passes. This intelligent approach balances reliability and performance by using dual SG scan operations to make informed decisions about when to trigger maintenance operations, improving the overall efficiency of the memory system by reducing unnecessary operations while maintaining data integrity.

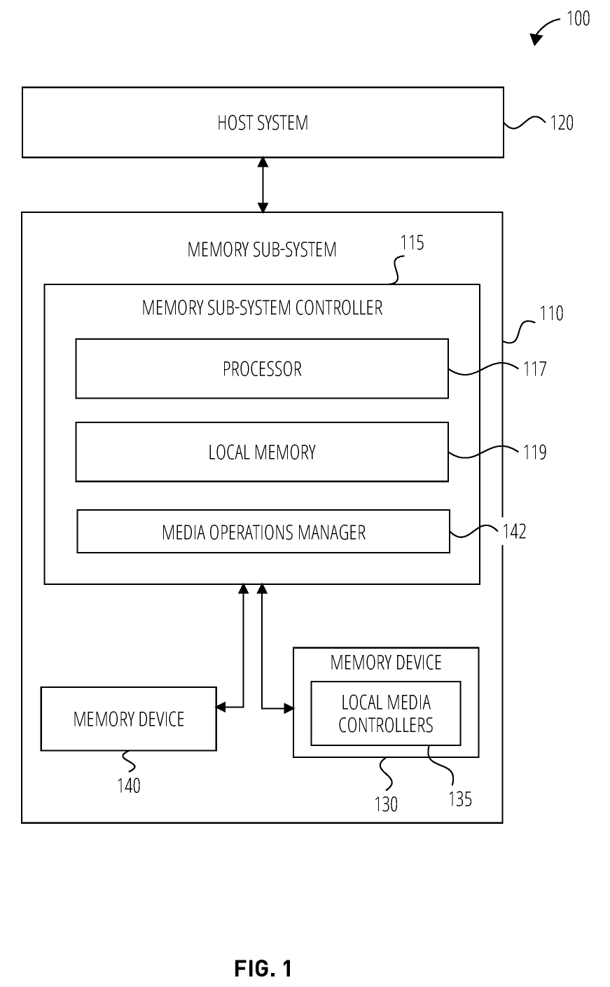

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.” In some cases, "processing device" can be referred to as "controller", "processor", "control circuitry"; "memory device" can be referred to as "memory component", "storage device", "memory array"; and "memory portion" can be referred to as "memory block", "memory segment", and/or "memory region."

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as "garbage collection data". “User data” can include host data and garbage collection data. "System data" hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package.

There are challenges in efficiently managing or performing media management operations on typical memory devices. SG maintenance is an important process in modern NAND memory systems that involves monitoring and managing the threshold voltages (VT) of SG structures. In Replacement Gate NAND devices, the SGs are designed to closely resemble array cells and have the capability to be both erased and reprogrammed. The primary purpose of SG maintenance is to periodically monitor the SG from the source side (SGS) and SG from the drain side (SGD) threshold voltages, such as after normal erase operations. This monitoring ensures that the SG VTs remain within predefined safe ranges for proper NAND block operation.

When SG VTs fall outside these safe ranges, the system can initiate special handling procedures to maintain proper functionality. These procedures typically involve two main types of maintenance operations, SG TU and special erase. SG TU involves programming the SG cells to adjust their threshold voltages. Special erase slightly programs the memory cells to a partially programmed state or slightly programmed state. A "slightly programmed state" refers to when the VT of the block is programmed to a level that is higher than an erased state but not as high as a fully programmed state. Special erase is particularly important before block retirement as it helps prevent leakage issues by ensuring cells achieve sufficiently higher VT levels. The maintenance process can begin after a normal erase operation, when the system performs SG scans to assess the state of the SGs. Based on these scan results, the system may make decisions about whether to perform TU operations, special erase operations, or ultimately retire the block to the grown bad block (GBB) pool if the maintenance operations cannot restore proper functionality. While maintaining proper SG VT levels is important for preventing leakage and ensuring proper operation, unnecessary maintenance operations can significantly impact system performance due to the substantial time required for TU and special erase operations. The SG maintenance operations comprise monitoring and managing threshold voltages of SG structures to maintain proper functionality of memory blocks. "SG structures" can be referred to as “select gate components” or "select gate elements."

The effectiveness of SG maintenance relies heavily on the system's ability to accurately assess the SG VT distribution and make intelligent decisions about when maintenance operations are truly necessary. This assessment process may need to be both precise enough to maintain reliability and efficient enough to optimize system performance. Conventional systems rely on a single verify level in the SG scan to determine maintenance needs, making broad assumptions about SG cell threshold voltage distributions being similar. This oversimplified approach triggers unnecessary touch-up operations whenever a low SG VT scan fails, consuming substantial processing time.

Current implementations compound these inefficiencies by performing multiple separate SG scan operations after performing TU operations. These include both low SG VT and high SG VT scans for screening. These additional SG scans create unnecessary system overhead. Some systems automatically activate special erase operations when the SG scans fail at low VT levels, based on the assumption that failing a low VT scan means the SG VT is too low to prevent leakage. This assumption is often incorrect, as many cells may still have VT levels sufficient to prevent leakage despite failing the low VT scan. With special erase operations taking approximately 5ms to complete, this "always on" approach results in significant wasted system resources.

The conventional single-verify approach also suffers from limited decision-making capability, providing only binary pass/fail results without additional data about actual VT distribution. This forces rigid decision paths rather than allowing optimization based on actual cell conditions. These inefficiencies are particularly impactful given the scale of SG maintenance operations in modern NAND devices, where multiple planes and blocks need periodic monitoring and maintenance.

The present disclosure addresses these technical challenges in memory systems by providing a memory sub-system controller that performs double-verify SG scan operations to obtain a more accurate distribution of SG VT levels and make intelligent decisions about maintenance operations. The controller performs a first SG scan operation to determine if voltage thresholds are within a safe range, followed by a second SG scan with different verification criteria for blocks that fail the first scan. This dual-scan approach enables the system to selectively perform maintenance operations, including TU programming and special erase, based on precise VT distribution data rather than relying on rigid, assumption-based decisions. By consolidating multiple SG scan steps into a single scan operation and avoiding unnecessary TU and special erase operations, the system improves efficiency while maintaining reliability. Additionally, the controller can implement reverse-order scanning, starting with the higher verify voltage, which provides faster scan performance and allows skipping the second scan when the first SG scan passes. This intelligent approach optimizes system performance by reducing unnecessary operations while ensuring proper data integrity and leakage prevention.

In some examples, a memory system can be configured to perform SG maintenance operations using a double-verify scanning approach. Specifically, the system includes a memory device coupled to a processing device that performs sequential SG scan operations with different verification parameters. The processing device can perform the scans in different orders. In some cases, a first SG scan applies a lower verify voltage followed by a second SG scan with a higher verify voltage. When the first lower-voltage SG scan fails, the processing device may skip the second SG scan since failing at the lower voltage indicates significant threshold voltage degradation.

In other implementations, the SG scan order is reversed, specifically starting with a higher verify voltage followed by a lower verify voltage scan. This reverse order approach allows skipping the second SG scan if the first high-voltage scan passes, since passing at a higher voltage implies passing at lower voltages. The reverse order can provide performance benefits of compared to forward order scanning. Performing the SG scan operations comprises performing sequential SG scans with different verification parameters in different orders. "Verification parameters" can be referred to as "verify criteria" or "verification thresholds"; and "scan orders" can be referred to as "verification sequences" or "scan sequences;" "touch-up programming" can be referred to as “TU operations” or "threshold adjustment programming;" and "special erase operations" can be referred to as "partial programming operations" or "leakage prevention operations."

The SG scan operations measure cell threshold voltages by applying verify voltages and counting how many cells are successfully read at each voltage level. The system compares the count of successfully read cells against predefined thresholds to determine pass/fail status. This double-verify approach provides more detailed information about the distribution of cell threshold voltages compared to single-verify approaches. Based on the SG scan results, the system selectively performs maintenance operations including SG TU programming to increase threshold voltages and special erase operations. In cases where both SG scans fail, both TU and special erase may be performed. When the first SG scan passes but the second fails (e.g., when applying a lower verify voltage results in reading a first amount of cells that fails to transgress a minimum threshold and the amount of cells read as a result of applying a higher verify voltage transgresses the minimum threshold), only TU may be needed without special erase. If both scans pass, no maintenance operations are required.

The SG scan pass/fail determination relies on a precise measurement system that evaluates memory cell threshold voltages (Vt). During each SG scan operation, the processing device applies a specific verify voltage to the gate and measures channel current flow to detect how many cells have threshold voltages below that verify level. The measurement process involves counting cells that can be successfully read at the applied voltage level and comparing this count against predetermined threshold values. When performing the double-verify scan approach, the processing device evaluates the results based on multiple voltage levels to obtain a more comprehensive view of the Vt distribution. If the number of cells with Vt below both verify levels exceeds the acceptable threshold, indicating significant threshold voltage degradation, both scans are considered failed. In cases where the first SG scan passes but the second scan fails, this indicates that while an acceptable number of cells maintain adequate Vt levels at the lower verify voltage, too many cells fail at the higher verify threshold. However, since the cells demonstrate sufficient Vt to prevent leakage at the lower level, only TU programming is necessary without requiring special erase operations. This targeted approach helps optimize maintenance operations based on the actual Vt distribution.

When both scans pass, it demonstrates that an acceptable number of cells maintain Vt levels above both verify thresholds, indicating the overall Vt distribution remains within the desired operating range. In this optimal scenario, no maintenance operations are required since the SG cells maintain sufficient threshold voltages to ensure proper operation. The system can be configured with different threshold numbers and verify voltage levels for each scan operation, allowing precise control over the Vt distribution measurement and maintenance decision process. This flexibility enables the system to adapt to specific requirements while maintaining optimal performance and reliability.

The special erase operation programs cells to a partially programmed state to prevent leakage current after block retirement. This maintenance approach helps optimize system performance by only performing necessary operations based on the detailed threshold voltage distribution information provided by the double-verify scanning. These operations can be performed as part of periodic monitoring or following normal erase operations. The processing device may ultimately categorize blocks that require special erase as grown bad blocks (GBB) that need to be retired.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WLGs, one or more blocks, one or more memory dies, and/or one or more pages) or group of memory components including the memory device 130, can be associated with a first reliability (capability) grade, value, measure, or lifetime PEC. The terms “reliability grade,” “value,” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC and current PEC and/or other conditions. In some examples, a memory or register can be associated with all of the memory components (memory device 130 and memory device 140) and can store a table that maps different groups, portions, bins or sets of the memory device 130 and memory device 140 to respective reliability grades, conditions, lifetime PEC values, and/or current PEC values.

The memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory modules (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells (e.g., including multi-level cell storage), such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or block stripes (BSs). As used herein, a block comprising SLCs can be referred to as a SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. The memory sub-system controller comprises hardware configured to perform operations including reading data, writing data, and erasing data at the memory devices.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can perform double-verify SG scan operations to intelligently determine when to perform SG maintenance operations. Specifically, when monitoring a portion of the memory device (e.g., a virtual block (VB) or memory block), the media operations manager 142 performs a first SG scan operation to determine if voltage thresholds are within a safe range. For memory portions that fail the first SG scan, the media operations manager 142 performs a second SG scan operation with different verification criteria to obtain a more accurate distribution of SG VT levels. The media operations manager 142 can selectively perform SG maintenance operations, including TU programming and/or special erase operations, based on the results of the two SG scan operations. When both SG scans fail, both TU and special erase operations may be performed. When the first scan passes but the second fails, only TU may be performed without special erase. When both scans pass, neither operation is needed. This approach prevents leakage issues while optimizing system performance by avoiding unnecessary special erase operations. The double-verify SG scan provides more precise information about the SG VT distribution, allowing the media operations manager 142 to determine if the VT levels are still high enough to prevent leakage even when failing a low SG VT scan. Additionally, the media operations manager 142 can perform the SG scans in reverse order, starting with the higher verify voltage, which provides faster scan performance and allows skipping the second scan if the first scan passes. This intelligent approach balances reliability and performance by using dual SG scan operations to make informed decisions about when to trigger maintenance operations, improving the overall efficiency of the memory system by reducing unnecessary operations while maintaining data integrity. "Media operations manager" can be referred to as “operations controller” or "memory operations manager;" and "safe range" can be referred to as "operational range" or "acceptable threshold range."

Any discussion with respect to the memory device 130 can similarly be applied to the memory device 140. Any function pertaining to the local media controllers 135 can, in some cases, be performed by the device) memory sub-system controller 115.

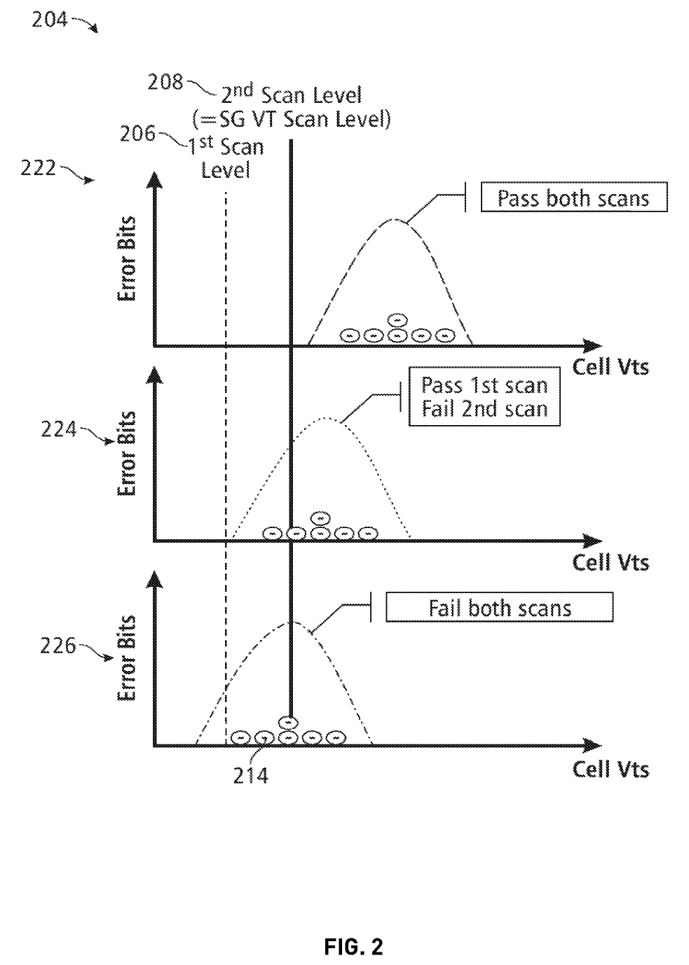

FIG. 2 illustrates diagrams of different results of performing SG scan operations, in accordance with some examples. Specifically, the media operations manager 142 can receive a request to erase a portion of the memory device 130, such as a memory block. In such cases, the media operations manager 142 can erase the memory block according to a first erase scheme or process in which all portions of the memory block are set to an erased state leaving no portion in a programmed state.

The media operations manager 142 can then determine whether the memory block is bad before returning the block for programming. The media operations manager 142 can do so by performing two SG scan operations including a first SG operation and a second SG scan operation on the memory block. In some cases, the media operations manager 142 selectively performs the second SG scan operation based on a result of performing the first SG scan operation. Also, the media operations manager 142 can select which of a set of SG maintenance operations (e.g., TU operations and/or special erase operations) to perform based on the first and/or second SG scan operations.

Specifically, the diagram 204 shows different results of performing the multiple SG scan operations. The diagram 204 includes three scenarios demonstrating how the media operations manager 142 evaluates cell threshold voltage distributions using two verify voltage levels (first verify voltage level 206 and second verify voltage level 208 associated with respective SG scan operations).

In some cases, the first scenario 222 shows a "Pass both scans" condition where the cell Vt distribution indicates an acceptable number of cells maintain threshold voltages above both the first verify voltage level 206 and the second verify voltage level 208. This distribution represents optimal memory block operation requiring no maintenance. In this circumstance, the result of applying the first verify voltage level 206 and the second verify voltage level 208 is that the number of cells that are successfully read remains below a threshold quantity.

The second scenario 224 labeled "Pass 1st Scan Fall 2nd Scan" depicts a distribution where cells pass the first verify voltage level 206 but fail at the higher second verify voltage level 208. This indicates the cells maintain sufficient Vt to prevent leakage at the lower threshold but show degradation at higher voltages. Namely, the result of applying the first verify voltage level 206 is that the number of cells that are successfully read remains below a threshold quantity whereas the result of applying the second verify voltage level 208 is that the number of cells that are successfully read transgresses the threshold quantity.

The third scenario 226 labeled "Fail both Scans" demonstrates significant Vt degradation where an unacceptable number of cells fail both verify levels, indicating severe condition requiring comprehensive maintenance operations. Namely, the result of applying the first verify voltage level 206 is that the number of cells that are successfully read transgresses a threshold quantity and the result of applying the second verify voltage level 208 is that the number of cells that are successfully read also transgresses the threshold quantity.

The vertical axis shown in each of the first scenario 222, second scenario 224, and third scenario 226 of each distribution plot represents number of cells being read 214. This visualization shows the number of cells falling below, between, or above the verify voltage levels.

When performing the first SG scan operation, the media operations manager 142 applies the first verify voltage level 206 to determine if voltage thresholds are within a safe operating range. The number of cells being read 214 successfully at this voltage level is compared against a predetermined threshold. For memory blocks passing the first SG scan, meaning an acceptable number of cells maintain Vt above the first verify voltage level 206 (e.g., the number of cells being read 214 is below the predetermined threshold), the media operations manager 142 proceeds with the second SG scan at a different second verify voltage level 208 to obtain a more complete picture of the Vt distribution. The second verify voltage level 208 serves as an additional checkpoint to evaluate overall memory block health. This higher verify level helps identify blocks that may require preventive maintenance despite passing the first SG scan.

The error bit distribution curves in scenarios (first scenario 222, second scenario 224, and third scenario 226) provide visual representation of cell Vt distributions relative to the verify levels. A wider distribution or shift toward lower voltages indicates degradation requiring maintenance.

In some cases, the first verify voltage level 206 that is applied is higher than the second verify voltage level 208 that is applied. This is referred to as the reverse order of operations. In such circumstances, different SG maintenance operations can be performed as a result of passing the first SG scan and failing the second SG scan or vice versa.

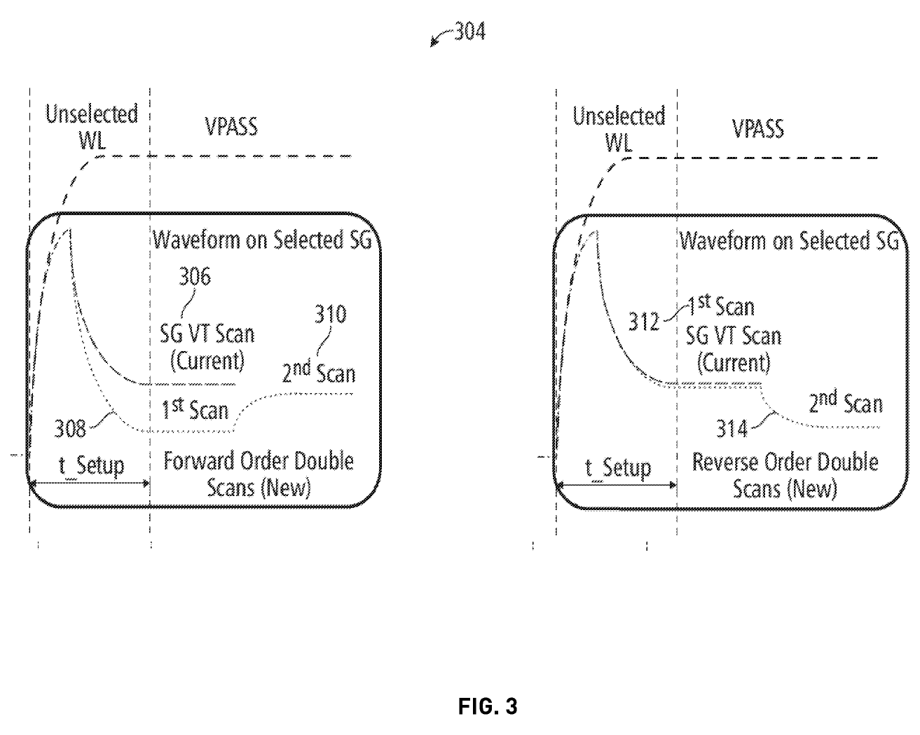

FIG. 3 illustrates a diagram 304 of waveforms for performing SG scan operations, in accordance with some examples. Specifically, the diagrams 304 illustrates waveforms for performing SG scan operations in both forward and reverse order configurations. The diagrams 304 shows multiple waveform diagrams demonstrating the timing and voltage levels applied during different scan approaches.

In the upper portion of the figure, an unselected wordline (WL) is shown receiving a VPASS voltage level. Below this, the waveform on the selected SG demonstrates the verify voltage that is applied for the first and second SG scans relative to conventional SG VT scans.

Specifically, for the forward order double scans configuration (shown on the left), the media operations manager 142 applies a setup time period (t_Setup) followed by two sequential SG scans. The first SG scan 308 applies a lower verify voltage than the low SG VT scan 306 of the conventional approach, followed by the second SG scan 310 at a higher verify voltage than the first SG scan 308 but that may be lower than the low SG VT scan 306 or at the same voltage level as the low SG VT scan 306.

In contrast, the reverse order double scans configuration (shown on the right) begins with the higher verify voltage scan (first SG scan 312 which may be at the same level as the low SG VT scan 306) followed by the lower verify voltage scan (second SG scan 314). This reverse order implementation provides an advantage that if the first SG scan passes at the higher voltage level, the media operations manager 142 can skip the second scan entirely since passing at a higher voltage implies passing at lower voltages.

Both configurations maintain the same basic waveform structure with the VPASS voltage applied to unselected wordlines and specific verify voltages applied to the selected SG during scan operations. The key difference lies in the sequence and potential optimization of skipping the second scan in reverse order mode.

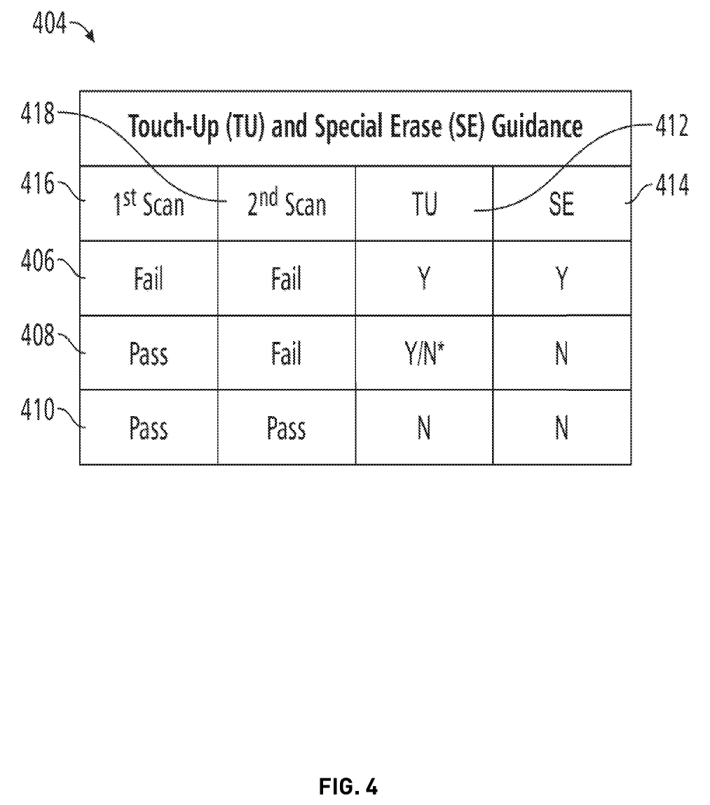

FIG. 4 illustrates a table 404 for performing SG maintenance operations, in accordance with some examples. Specifically, the table 404 shows the guidance for the media operations manager 142 in selectively performing SG maintenance operations. For example, the table 404 guides whether the media operations manager 142 performs TU and/or special erase (SE) operations based on different SG scan results in the forward configuration.

The table 404 includes columns for the first SG scan 416, second SG scan 418, TU operation 412, and special erase operation 414. Each row represents a different scenario based on the forward SG scan results. In the first scenario 406 of the forward configuration, when the media operations manager 142 determines that the memory portion being scanned fails both the first and second SG scans. In such cases, according to the table 404, the media operations manager 142 determines that both touch-up (Y) and special erase (Y) operations need to be performed. This represents the most severe case of threshold voltage degradation. Specifically, the media operations manager 142 applies a first verify voltage level to the memory portion and reads data to measure how many cells are successfully read. If the number of successfully read cells transgresses a first threshold number, the first SG scan fails. The media operations manager 142 then applies a second, higher verify voltage level to the memory portion and reads additional data to measure how many cells are successfully read at this higher level. If the number of cells successfully read at this higher level also transgresses a second threshold number, the second SG scan fails. When both SG scans fail in this manner, indicating severe threshold voltage degradation across multiple voltage levels, the table 404 directs the media operations manager 142 to perform both touch-up (Y) and special erase (Y) operations.

The second scenario 408 shows when the first SG scan passes but the second SG scan fails. In this case, the table indicates touch-up may be performed (Y/N*) but special erase is not needed (N). The Y/N* notation indicates touch-up is optional depending on process maturity. For example, the media operations manager 142 applies a lower verify voltage level to the memory portion and reads data to measure how many cells are successfully read. When the number of successfully read cells remains below a first threshold number, the first SG scan passes, indicating sufficient threshold voltage at the lower level. The media operations manager 142 then applies a second, higher verify voltage level and reads additional data. If the number of cells successfully read at this higher level transgresses a second threshold number, the second SG scan fails. This pattern indicates that while the cells maintain adequate threshold voltage to prevent leakage at the lower verify level, some degradation has occurred at higher voltages. Based on this determination, the table 404 indicates touch-up programming may be performed (Y/N*) but special erase is not needed (N), since the cells demonstrate sufficient threshold voltage to prevent leakage. The optionality of the touch-up operation (indicated by Y/N*) depends on process maturity. In mature processes with well-developed trim sets, touch-up can effectively raise the threshold voltage to desired levels, while in less mature processes, touch-up may risk over-programming and is therefore skipped.

The third scenario 410 represents the optimal case where both SG scans pass, which the media operations manager 142 determines through sequential verification steps. During the first scan, the media operations manager 142 applies a lower verify voltage level to the memory portion and measures how many cells are successfully read. When the number of cells successfully read remains below a first threshold number, the first SG scan passes. The media operations manager 142 then applies a second, higher verify voltage level and measures the number of cells successfully read at this higher level. When this number also remains below a second threshold number, the second SG scan passes. This dual-passing result indicates that an acceptable number of cells maintain threshold voltages above both verify levels, demonstrating the memory block's voltage distribution remains within the desired operating range. In this optimal scenario, the table 404 indicates neither touch-up (N) nor special erase (N) operations are required since the SG cells maintain sufficient threshold voltages to ensure proper operation and prevent leakage.

For the forward configuration, the first SG scan applies a lower verify voltage than the second SG scan. This means passing the first SG scan indicates cells maintain minimum acceptable threshold voltages, while failing the second SG scan suggests degradation at higher voltage levels.

When implementing the reverse configuration, where the first scan applies a higher verify voltage than the second scan, the table's interpretation changes. In the reverse configuration's first scenario, failing both SG scans still indicates severe degradation requiring both touch-up and special erase operations, similar to the forward configuration. However, the second scenario in reverse configuration represents a different condition of passing the higher voltage SG scan but failing at the lower voltage. This unusual pattern may indicate different maintenance requirements.

The third scenario in reverse configuration maintains the same interpretation of passing both scans requires no maintenance operations. The reverse configuration including passing the first scan (at higher voltage) allows skipping the second scan entirely, since passing at a higher voltage implies passing at lower voltages. This optimization in the reverse configuration can reduce the number of required scan operations, improving overall system performance.

For the reverse configuration, the table may be modified to reflect that the second SG scan may be skipped when the first SG scan passes, potentially eliminating the second and third scenarios in many cases. The reverse configuration's table may also account for the different voltage sequence, where the first scan's higher voltage provides a more stringent initial test of cell threshold voltages.

In both configurations, the table 404 serves as a decision matrix for determining appropriate maintenance operations based on scan results, helping optimize system performance while maintaining reliability. The difference between the forward and reverse configuration tables lies in the sequence of verify voltages and the potential to skip the second scan in the reverse configuration.

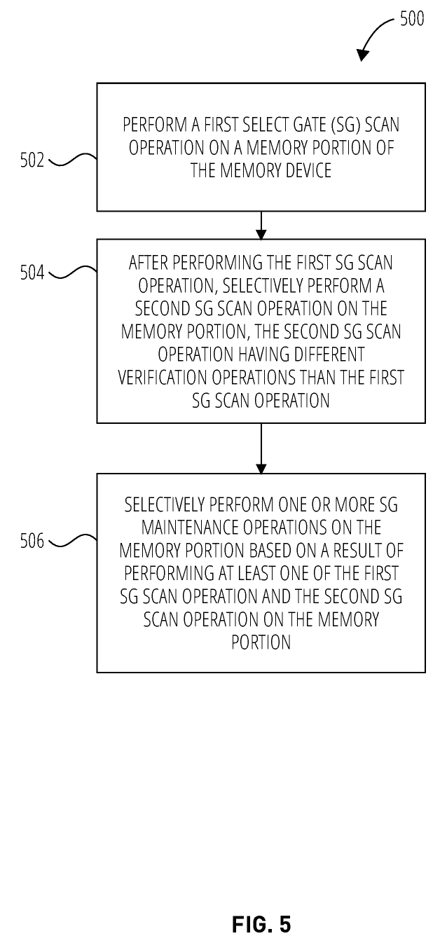

FIG. 5 illustrates a diagram 500 of operations performed using the media operations manager 142, in accordance with some examples. The method or process of diagram 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 500 is performed by the memory sub-system controller 115, local media controllers 135, and/or subcomponents of the memory sub-system controller 115 and/or local media controllers 135 of FIG. 1. In these examples, the method or process of diagram 500 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 5, the method begins at operation 502 where the media operations manager 142 performs a first SG scan operation on a memory portion of the memory device 130. During this operation, the media operations manager 142 applies a verify voltage to the memory portion and measures how many cells are successfully read at that voltage level, comparing the count against a predetermined threshold to determine if the voltage thresholds are within a safe operating range.

At operation 504, when the media operations manager 142 determines the memory portion fails the first SG scan operation (e.g., the number of successfully read cells transgresses the threshold), the media operations manager 142 selectively performs a second SG scan operation on the memory portion. This second scan uses different verification parameters than the first scan, such as applying a different verify voltage level or using a different threshold number for determining pass/fail status.

At operation 506, based on the results of both scan operations, the media operations manager 142 selectively performs maintenance operations on the memory portion. These maintenance operations may include TU programming to increase threshold voltages and/or special erase operations that program cells to a partially programmed state to prevent leakage current. The specific maintenance operations performed depend on whether the memory portion failed one or both SG scans, with both operations performed when both scans fail.

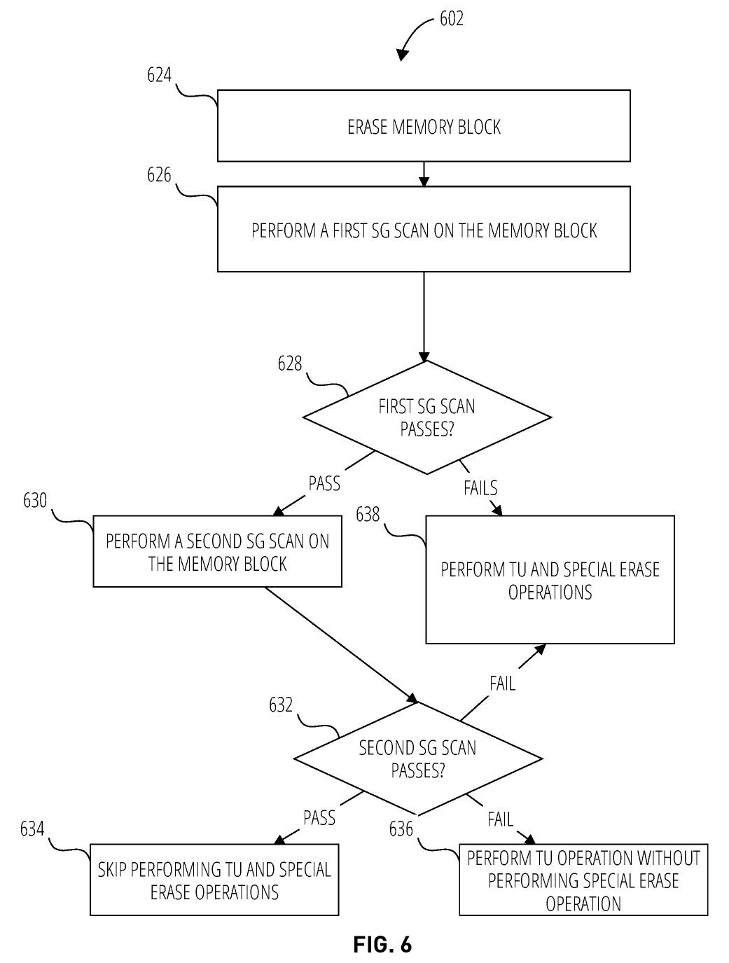

FIG. 6 illustrates a diagram 602 of operations performed using the media operations manager 142, in accordance with some examples. The method or process of diagram 602 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 602 is performed by the memory sub-system controller 115, local media controllers 135, and/or subcomponents of the memory sub-system controller 115 and/or local media controllers 135 of FIG. 1. In these examples, the method or process of diagram 602 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 6, the method begins at operation 624 where the media operations manager 142 erases a memory block. At operation 626, the media operations manager 142 performs a first SG scan on the memory block. At operation 628, the media operations manager 142 determines whether the first SG scan passes or fails (e.g., whether the memory block being read passes or fails the first SG scan). If the first SG scan fails at operation 630, the media operations manager 142 proceeds to operation 638 where both TU and special erase operations are performed on the memory block by the media operations manager 142.

If the first SG scan passes at operation 628, the media operations manager 142 proceeds to operation 630 where the media operations manager 142 performs a second SG scan on the memory block. At operation 632, the media operations manager 142 determines whether the second SG scan passes or fails. If the second SG scan fails, the media operations manager 142 proceeds to operation 636 where the media operations manager 142 performs a TU operation without performing a special erase operation, since passing the first scan indicates sufficient threshold voltage to prevent leakage.

If the second SG scan passes at operation 632, the media operations manager 142 proceeds to operation 634 where the media operations manager 142 skips performing both TU and special erase operations, since passing both scans indicates the memory block maintains adequate threshold voltages for proper operation.

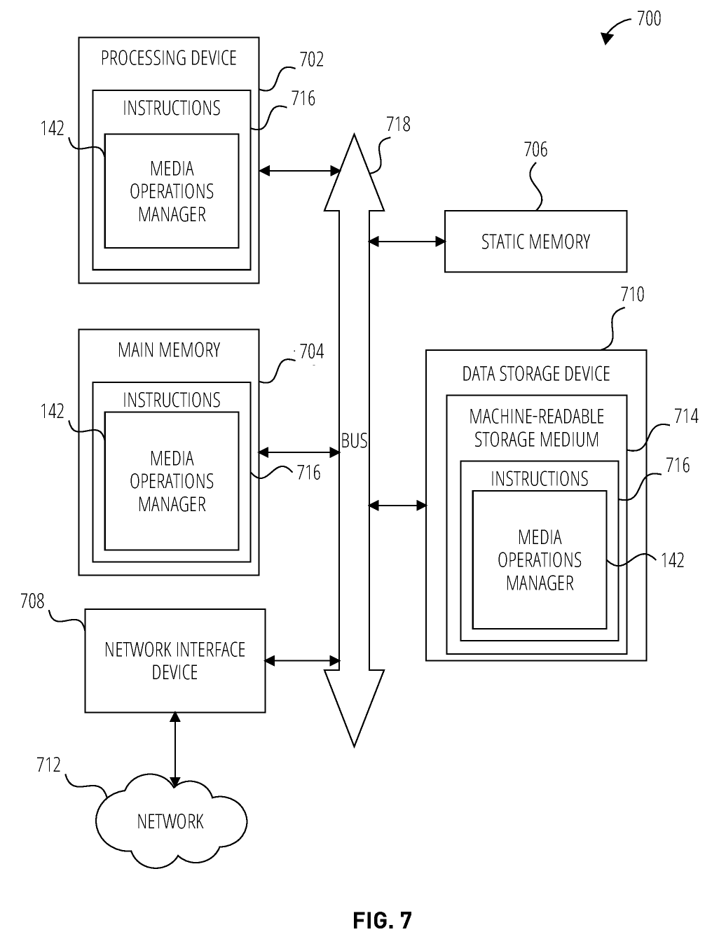

FIG. 7 illustrates an example machine in the form of a computer system 700 within which a set of instructions can be executed for causing the machine to perform any one or more of the methodologies discussed herein. In some examples, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., ROM, flash memory, DRAM such as SDRAM or Rambus DRAM (RDRAM), etc.), a static memory 706 (e.g., flash memory, static random access memory (SRAM), etc.), and a data storage device 710, which communicate with each other via a bus 718.

The processing device 702 represents one or more general-purpose processing devices such as a microprocessor, a central processing unit, or the like. More particularly, the processing device 702 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 702 can also be one or more special-purpose processing devices such as an application-specific integrated circuit (ASIC), a field programmable gate array (FPGA), a digital signal processor (DSP), a network processor, or the like. The processing device 702 is configured to execute instructions 716 for performing the operations and steps discussed herein. The computer system 700 can further include a network interface device 708 to communicate over a network 712.

The data storage device 710 can include a machine-readable storage medium 714 (also known as a computer-readable medium) on which is stored one or more sets of instructions 716 or software embodying any one or more of the methodologies or functions described herein. The instructions 716 can also reside, completely or at least partially, within the main memory 704 and/or within the processing device 702 during execution thereof by the computer system 700, the main memory 704 and the processing device 702 also constituting machine-readable storage media. The machine-readable storage medium 714, data storage device 710, and/or main memory 704 can correspond to the memory sub-system 110 of FIG. 1.

In one example, the instructions 716 include instructions to implement functionality corresponding to providing block failure protection for a zone memory sub-system as described herein. While the machine-readable storage medium 714 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: performing a first select gate (SG) scan operation on a memory portion of the memory device; after performing the first SG scan operation, selectively performing a second SG scan operation on the memory portion, the second SG scan operation having different verification operations than the first SG scan operation; and selectively performing one or more SG maintenance operations on the memory portion based on a result of performing at least one of the first SG scan operation and the second SG scan operation on the memory portion.

Example 2. The system of Example 1, wherein the first SG scan operation applies a lower verify voltage than the second SG scan operation, the operations comprising: skipping the second SG scan operation in response to determining that the memory portion fails the first SG scan operation.

Example 3. The system of any one of Examples 1-2, wherein the first SG scan operation applies a higher verify voltage than the second SG scan operation, the operations comprising: skipping the second SG scan operation in response to determining that the memory portion passes the first SG scan operation.

Example 4. The system of any one of Examples 1-3, wherein the different verification operations comprise at least one of a different threshold number of passing memory cells for passing the second SG scan operation or a different read threshold voltage applied to the memory portion.

Example 5. The system of Example 4, wherein the first SG scan operation comprises: applying a first verify voltage level to the memory portion; reading data from the memory portion in response to applying the first verify voltage level; measuring a number of memory cells that are successfully read as part of reading the data; comparing the number of memory cells to a first threshold number; and determining whether the memory portion fails the first SG scan operation in response to comparing that the number of memory cells to the first threshold number.

Example 6. The system of Example 5, wherein the second SG scan operation comprises: applying a second verify voltage level to the memory portion, the second verify voltage level being different than the first verify voltage level; reading additional data from the memory portion in response to applying the second verify voltage level; measuring an additional number of memory cells that are successfully read as part of reading the additional data; comparing the additional number of memory cells to a second threshold number; and determining that the memory portion fails the second SG scan operation in response to determining that the additional number of memory cells fails to transgress the second threshold number.

Example 7. The system of any one of Examples 1-6, wherein the one or more SG maintenance operations comprise a special erase operation that programs a specified set of regions of the memory portion into a programmed state and an SG touch-up (TU) operation that increases an SG threshold voltage of the memory portion.

Example 8. The system of Example 7, the operations comprising: determining that the memory portion passes the first SG scan operation; in response to determining that the memory portion passes the first SG scan operation, performing the second SG scan operation; and performing the SG TU operation while skipping the special erase operation in response to determining that the memory portion fails the second SG scan operation.

Example 9. The system of any one of Examples 7-8, the operations comprising: determining that the memory portion fails the first SG scan operation; in response to determining that the memory portion fails the second SG scan operation, performing the second SG scan operation; and performing both the SG TU operation and the special erase operation on the memory portion in response to determining that the memory portion fails the second SG scan operation.

Example 10. The system of Example 9, the operations comprising: in response to performing the special erase operation on the memory portion, categorizing the memory portion as a grown bad block (GBB).

Example 11. The system of any one of Examples 9-10, wherein the special erase operation programs the memory portion to prevent leakage current from impacting operations of other memory portions.

Example 12. The system of any one of Examples 1-11, wherein the one or more SG maintenance operations comprise a special erase operation to program memory cells to a partially programmed state.

Example 13. The system of any one of Examples 1-12, wherein the one or more SG maintenance operations comprise a select gate touch-up operation to program select gate cells to increase SG threshold voltage.

Example 14. The system of any one of Examples 1-13, wherein selectively performing the one or more SG maintenance operations comprises: performing both a select gate touch-up operation and a special erase operation in response to determining that the memory portion fails both the first and second SG scan operations.

Example 15. The system of any one of Examples 1-14, wherein selectively performing the one or more SG maintenance operations comprises: performing a select gate touch-up operation without performing a special erase operation in response to determining that the memory portion passes the first SG scan operation but fails the second SG scan operation.

Example 16. The system of any one of Examples 1-15, wherein selectively performing the one or more SG maintenance operations comprises: skipping performing a select gate touch-up operation and a special erase operation in response to determining that the memory portion passes both the first and second SG scan operations.

Example 17. The system of any one of Examples 1-16, wherein the first and second SG scan operations are performed as part of a periodic monitoring process or after a normal erase operation is performed on the memory portion.

Example 18. The system of any one of Examples 1-17, wherein the memory device comprises a three-dimensional (3D) NAND device.

Example 19. At least one non-transitory machine-readable storage medium comprising instructions that, when executed by a processing device, cause the processing device to perform operations comprising: performing a first select gate (SG) scan operation on a memory portion of a memory device; after performing the first SG scan operation, selectively performing a second SG scan operation on the memory portion, the second SG scan operation having different verification operations than the first SG scan operation; and selectively performing one or more SG maintenance operations on the memory portion based on a result of performing at least one of the first SG scan operation and the second SG scan operation on the memory portion.

Example 20. A method comprising: performing a first select gate (SG) scan operation on a memory portion of a memory device; after performing the first SG scan operation, selectively performing a second SG scan operation on the memory portion, the second SG scan operation having different verification operations than the first SG scan operation; and selectively performing one or more SG maintenance operations on the memory portion based on a result of performing at least one of the first SG scan operation and the second SG scan operation on the memory portion.

The term “coupled with” generally refers to a connection between components, which can be an indirect communicative connection or direct communicative connection (e.g., without intervening components), whether wired or wireless, including connections such as electrical, optical, magnetic, and the like.

“System data” as used herein refers to data that is created and/or maintained by the memory sub-system for performing operations in response to host requests and for media management.

“User data” as used herein generally refers to host data and garbage collection data.

"Grown bad block (GBB)" refers to a memory block that has been retired from normal operation due to Select Gate (SG) scan failures or other failures.

“Retiring” as used herein refers to the process of removing NAND blocks from normal operation when they fail certain quality checks, specifically Select Gate (SG) scan tests.

"SG scan" refers to a periodic monitoring process that checks the Select Gate voltage threshold (VT) levels in NAND blocks. The scan reads data from cells using specific verify levels to determine if the number of cells passing that level exceeds a defined threshold. The process can involve applying a verify voltage level to the wordline; reading how many cells pass this voltage threshold; comparing the count of passing cells against a predetermined threshold; and determining pass/fail status based on whether enough cells meet the criteria. The primary purpose of SG scan is to monitor if Select Gate VTs remain within a designated safe range defined for normal NAND block operations. If VTs fall outside this safe range, the scan is marked as failed, which can trigger additional operations before block retirement.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled to the memory device, configured to perform operations comprising:
performing a first select gate (SG) scan operation on a memory portion of the memory device;
after performing the first SG scan operation, selectively performing a second SG scan operation on the memory portion, the second SG scan operation having different verification operations than the first SG scan operation; and
selectively performing one or more SG maintenance operations on the memory portion based on a result of performing at least one of the first SG scan operation and the second SG scan operation on the memory portion.

2. The system of claim 1, wherein the first SG scan operation applies a lower verify voltage than the second SG scan operation, the operations comprising:
skipping the second SG scan operation in response to determining that the memory portion fails the first SG scan operation.

3. The system of claim 1, wherein the first SG scan operation applies a higher verify voltage than the second SG scan operation, the operations comprising:
skipping the second SG scan operation in response to determining that the memory portion passes the first SG scan operation.

4. The system of claim 1, wherein the different verification operations comprise at least one of a different threshold number of passing memory cells for passing the second SG scan operation or a different read threshold voltage applied to the memory portion.

5. The system of claim 4, wherein the first SG scan operation comprises:
applying a first verify voltage level to the memory portion;
reading data from the memory portion in response to applying the first verify voltage level;
measuring a number of memory cells that are successfully read as part of reading the data;
comparing the number of memory cells to a first threshold number; and
determining whether the memory portion fails the first SG scan operation in response to comparing that the number of memory cells to the first threshold number.

6. The system of claim 5, wherein the second SG scan operation comprises:
applying a second verify voltage level to the memory portion, the second verify voltage level being different than the first verify voltage level;
reading additional data from the memory portion in response to applying the second verify voltage level;
measuring an additional number of memory cells that are successfully read as part of reading the additional data;
comparing the additional number of memory cells to a second threshold number; and
determining that the memory portion fails the second SG scan operation in response to determining that the additional number of memory cells fails to transgress the second threshold number.

7. The system of claim 1, wherein the one or more SG maintenance operations comprise a special erase operation that programs a specified set of regions of the memory portion into a programmed state and an SG touch-up (TU) operation that increases an SG threshold voltage of the memory portion.

8. The system of claim 7, the operations comprising:
determining that the memory portion passes the first SG scan operation;
in response to determining that the memory portion passes the first SG scan operation, performing the second SG scan operation; and
performing the SG TU operation while skipping the special erase operation in response to determining that the memory portion fails the second SG scan operation.

9. The system of claim 7, the operations comprising:
determining that the memory portion fails the first SG scan operation;
in response to determining that the memory portion fails the second SG scan operation, performing the second SG scan operation; and
performing both the SG TU operation and the special erase operation on the memory portion in response to determining that the memory portion fails the second SG scan operation.

10. The system of claim 9, the operations comprising:
in response to performing the special erase operation on the memory portion, categorizing the memory portion as a grown bad block (GBB).

11. The system of claim 9, wherein the special erase operation programs the memory portion to prevent leakage current from impacting operations of other memory portions.

12. The system of claim 1, wherein the one or more SG maintenance operations comprise a special erase operation to program memory cells to a partially programmed state.

13. The system of claim 1, wherein the one or more SG maintenance operations comprise a select gate touch-up operation to program select gate cells to increase SG threshold voltage.

14. The system of claim 1, wherein selectively performing the one or more SG maintenance operations comprises:
performing both a select gate touch-up operation and a special erase operation in response to determining that the memory portion fails both the first and second SG scan operations.

15. The system of claim 1, wherein selectively performing the one or more SG maintenance operations comprises:
performing a select gate touch-up operation without performing a special erase operation in response to determining that the memory portion passes the first SG scan operation but fails the second SG scan operation.

16. The system of claim 1, wherein selectively performing the one or more SG maintenance operations comprises:
skipping performing a select gate touch-up operation and a special erase operation in response to determining that the memory portion passes both the first and second SG scan operations.

17. The system of claim 1, wherein the first and second SG scan operations are performed as part of a periodic monitoring process or after a normal erase operation is performed on the memory portion.

18. The system of claim 1, wherein the memory device comprises a three-dimensional (3D) NAND device.

19. At least one non-transitory machine-readable storage medium comprising instructions that, when executed by a processing device, cause the processing device to perform operations comprising:
performing a first select gate (SG) scan operation on a memory portion of a memory device;
after performing the first SG scan operation, selectively performing a second SG scan operation on the memory portion, the second SG scan operation having different verification operations than the first SG scan operation; and
selectively performing one or more SG maintenance operations on the memory portion based on a result of performing at least one of the first SG scan operation and the second SG scan operation on the memory portion.

20. A method comprising:
performing a first select gate (SG) scan operation on a memory portion of a memory device;
after performing the first SG scan operation, selectively performing a second SG scan operation on the memory portion, the second SG scan operation having different verification operations than the first SG scan operation; and
selectively performing one or more SG maintenance operations on the memory portion based on a result of performing at least one of the first SG scan operation and the second SG scan operation on the memory portion.
